(19) United States
(12) Patent Application Publication
(10) Pub. No.: US 2025/0237727 A1
(43) Pub. Date: Jul. 24, 2025

(54) DETERMINING INTERFERENCE IN A TEST CHANNEL

(71) Applicant: LitePoint Corporation, San Jose, CA (US)

(72) Inventors: Chen Cao, Shanghai (CN); Christian Volf Olgaard, Saratoga, CA (US); Ruizu Wang, San Jose, CA (US); Qingjie Lu, Shanghai (CN)

(73) Assignee: LitePoint Corporation, San Jose, CA (US)

(21) Appl. No.: 18/432,774

(22) Filed: Feb. 5, 2024

(30) Foreign Application Priority Data
Jan. 24, 2024 (CN) 202410097776.3

(51) Int. Cl. G01R 35/00; G01R 27/26

(52) U.S. Cl. CPC G01R 35/005; G01R 27/26

(57) ABSTRACT

An example test system includes a signal receiver configured to receive (i) a reference signal and (ii) a test channel signal, and one or more processing devices configured to compare a version of the reference signal to a version of the test channel signal to determine whether there is a predefined amount of interference in the test channel signal.

### TECHNICAL FIELD

This specification describes example implementations of techniques for determining interference in a test channel.

### BACKGROUND

Interference may include electrical signals that can affect communication between devices. In the context of testing electronic devices, interference in a test channel can adversely affect testing performed by a test system on a device under test (DUT).

### SUMMARY

An example test system includes a signal receiver configured to receive (i) a reference signal and (ii) a test channel signal, and one or more processing devices configured to compare a version of the reference signal to a version of the test channel signal to determine whether there is a predefined amount of interference in the test channel signal. The example test system may include one or more of the following features, either alone or in combination.

The test system may include a signal generator configured to output the reference signal. The signal receiver may be configured to receive the reference signal from the signal generator and to receive at least part of the test channel signal from the test channel. The test channel signal may include at least part of a copy of the reference signal. The one or more processing devices may be configured to compare the version of the reference signal to the version of the test channel signal to determine if there is a difference between the version of the reference signal and the version of the test channel signal.

If the difference is less than a predefined threshold, then the test channel signal does not have the predefined amount of interference. If the difference is greater than the predefined threshold, then the test channel signal does have the predefined amount of interference. The one or more processing devices may be configured to cause the signal generator to output a copy of reference signal again if the difference is greater than the predefined threshold. The predefined threshold may be based, at least in part, on radio frequency (RF) and baseband stability of the test system.

The signal generator may include a vector signal generator (VSG). The signal receiver may include a vector signal analyzer (VSA) and an antenna. The test system further may include switches configured to connect the VSG to the VSA in a first configuration, to connect the VSG to the antenna in a second configuration, and to connect the VSA to the antenna in the second configuration.

Determining whether there is the predefined amount of interference in the test channel signal may include performing a correlation between the version of the reference signal and the version of the test channel signal. The one or more processing devices may be configured to synchronize the version of the reference signal and the version of the test channel signal prior to determining whether there is the predefined amount of interference in the test channel signal.

The reference signal and the test channel signal may include radio frequency (RF) signals. The test channel may be a wireless test channel. The test channel may be a wired test channel. The test channel signal may include at least one of interference from one or more other signals in the test channel or a signal directed to the test system by a device under test (DUT). The test channel signal may include a data packet that will cause an acknowledgement if received by a device.

When the one or more processing devices determine that there is the predefined amount of interference in the test channel signal, the one or more processing devices may be configured to ignore data packets from the test channel.

An example method includes receiving, at a signal receiver, (i) a reference signal and (ii) a test channel signal; and comparing a version of the reference signal to a version of the test channel signal to determine whether there is a predefined amount of interference in the test channel signal. The example method may include one or more of the following features, either alone or in combination.

The method may include outputting the reference signal from a signal generator. The signal receiver may receive the reference signal from the signal generator and receive at least part of the test channel signal from the test channel. The test channel signal may include at least part of a copy of the reference signal. Comparing the version of the reference signal to the version of the test channel signal may include comparing the version of the reference signal to the version of the test channel signal to determine if there is a difference between the version of the reference signal and the version of the test channel signal.

If the difference is less than a predefined threshold, then the test channel signal does not have the predefined amount of interference. If the difference is greater than the predefined threshold, then the test channel signal does have the predefined amount of interference. The method may include causing the signal generator to output a copy of reference signal again if the difference is greater than a predefined threshold. The predefined threshold is based, at least in part, on radio frequency (RF) and baseband stability of a system that performs the method.

The signal generator may include a vector signal generator (VSG). The signal receiver may include a vector signal analyzer (VSA) and an antenna. The method may include configuring switches to connect the VSG to the VSA in a first configuration, to connect the VSG to the antenna in a second configuration, or to connect the VSA to the antenna in a second configuration.

Determining whether there is the predefined amount of interference in the test channel signal may include performing a correlation between the version of the reference signal and the version of the test channel signal. The method may include synchronizing the version of the reference signal and the version of the test channel signal prior to determining whether there is interference in the test channel signal. The reference signal and the test channel signal may include radio frequency (RF) signals. The test channel may include a wireless test channel. The test channel may include a wired test channel.

The test channel signal may include at least one of interference from one or more other signals in the test channel or a signal directed to a system that performs the method by the DUT. The test channel signal may include a data packet that will cause an acknowledgement if received by a device. When there is the predefined amount of interference in the test channel signal, the method may include ignoring data packets from the test channel.

An example test system includes a signal generator to output a data packet to a test channel; a signal receiver configured to receive (i) a reference signal and (ii) a test channel signal; and one or more processing devices configured to compare a version of the reference signal to a version of the test channel signal to make an inference about whether a data packet reached a device under test (DUT) via the test channel, and to determine a performance metric based on the inference. The example test system may include one or more of the following features, either alone or in combination.

The one or more processing devices may be configured to ignore data packets on the test channel if the inference is that the data packet did not reach the DUT. The one or more processing devices may be configured to determine that there is a predefined amount of interference on the test channel if a difference between the version of the reference signal and the version of the test channel signal exceeds a threshold. The inference may be that the data packet did not reach the DUT if the predefined amount of interference is determined. The one or more processing devices may be configured to cause the signal receiver to implement a long capture comprised of a predefined number of data packets when interference is detected. The one or more processing devices may be configured to output a trigger in response to determining that there is the predefined amount of interference on the test channel. The trigger may be for instructing that further action be taken. The one or more processing devices may be configured to ignore data packets that are received when there is the predefined amount of interference on the test channel. The performance metric may include a packet error rate.

Any two or more of the features described in this specification, including in this summary section, may be combined to form implementations not specifically described in this specification.

At least part of the devices, systems, and processes described in this specification may be configured, controlled, and/or implemented by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, systems, and processes described in this specification may be configured, controlled and/or implemented using a computing system comprised of one or more processing devices and memory storing instructions that are executable by the one or more processing devices to perform various control operations. The devices, systems, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is a block diagram showing example circuitry configured to determine interference on a test channel.

FIG. 2 is a block diagram showing the circuitry of FIG. 1 in a first switch configuration.

FIG. 3 is a block diagram showing the circuitry of FIG. 1 in a second switch configuration that is different from the first switch configuration.

FIG. 4 is a flowchart showing operations included in an example process for determining interference on a test channel.

FIG. 5 is block diagram showing an example variant of the circuitry of FIG. 1.

FIG. 6 is a graph showing cross-correlation values of signals captured from a test channel when there is known to be no interference on the test channel, and noise generated by the test system that corresponds to those cross-correlation values.

FIG. 7 is graph showing correlation values for different interference signal powers.

FIG. 8 is a block diagram of components of example automatic test equipment containing circuitry like that of FIGS. 1 to 3 and 5.

Like reference numerals in different figures indicate like elements.

### DETAILED DESCRIPTION

Test systems, such as automatic test equipment (ATE), are configured to test the operation of electronic devices referred to as devices under test (DUTs). Examples of DUTs that may be tested by a test system includes electronic devices such as wireless transmitters or microprocessors, and system-level devices such as smartphones.

A test system may include test instruments to test a DUT. Part of the testing process may include passing signals, including data packets, over one or more test channels between a test instrument and the DUT. An example test channel may be or include airborne/wireless transmission media and/or wired transmission media. Interference, particularly on a wireless test channel, may adversely affect communication between the DUT and the test instrument. Interference may include electrical signals on the test channel that affect the communication. For example, interference may include stray electrical signals in the environment and/or electrical signals destined for, or received from, other DUTs being tested or other devices that are not being tested. For example, interference may result from collisions of data packets. A data packet collision may be caused by the simultaneous transmission of two or more data packets onto the test channel by two or more devices.

The amount of interference that can be tolerated by a DUT is referred to herein as an acceptable amount of interference. If more than an acceptable amount of interference is present in a test channel, which is referred to herein as an unacceptable amount of interference, communication between the DUT and the test instrument may be adversely affected. In an example, unacceptable amounts of interference may interfere with transmission and/or reception of data packets. In another example, unacceptable amounts of interference may corrupt data packets during transmission preventing the DUT and/or the test instrument from decoding the data packets.

Described herein are examples of systems and processes for determining whether there is greater than a predefined amount—for example, an unacceptable amount—of interference on a test channel and for taking action based on whether there is greater than the predefined amount of interference on the test channel. For example, if a test system, or a component thereof such as a test instrument, determines that there is an unacceptable amount of interference on the test channel, the test system may resend test signals, including data packets, to the DUT. By causing the test system to resend signals when there is an unacceptable amount of interference on the test channel, the likelihood of the test system and/or the DUT receiving signals that are transmitted, and being able to understand those signals, may be increased. In addition, by analyzing a source signal, the systems and processes can infer whether the signal is degraded at the DUT and then flag such a condition and take appropriate action.

In some implementations, the example systems and processes may be configured to determine a performance metric, such as a bit error rate (BER) or packet error rate (PER), for communications between the test system and the DUT. A BER is a metric relating to signal integrity and is a measure based on the number of bits transmitted by a first device that were received by a second device. A PER is a metric relating to signal integrity and is a measure based on the number of data packets transmitted by a first device that were received by a second device.

The test system, or a component thereof such as a test instrument, may make an inference about whether a data packet reached a DUT via the test channel based on the amount of interference determined to be in the test channel. The test system may determine the performance metric based on this inference. For example, if the inference is that data packets reached the DUT, the PER may be determined to be less than if the inference is that the data packets did not reach the DUT.

In some implementations, the example systems and processes may be configured to ignore data packets when it is determined that there is an unacceptable amount of interference in the test channel. For example, a test instrument transmitter counter may ignore a data packet when the data packet is flagged as being among an unacceptable level of interference. By ignoring data packets under these circumstances, the test system reduces the chances that data packets corrupted by interference will be relied upon during testing.

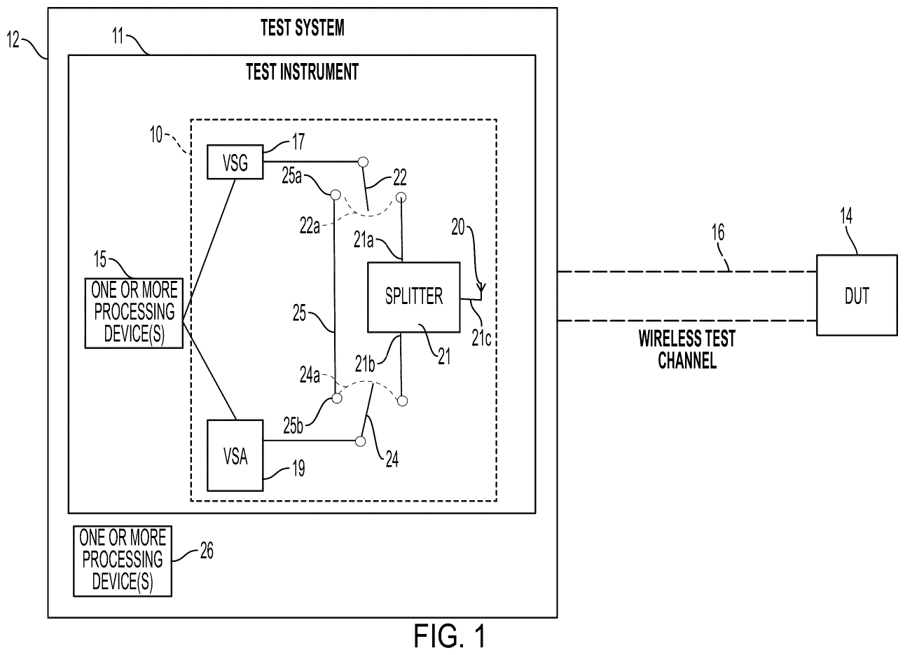

FIG. 1 is a block diagram of example circuitry 10 that may be included in an example test system 12. Circuitry 10 is for use in example processes that determine whether there is interference in a test channel. In this example, circuitry 10 is part of a test instrument 11 on test system 12; however, circuitry 10 may be included in components of the test system other than a test instrument. In this example, circuitry 10 is configured to communicate with a DUT 14 wirelessly, as described below. DUT 14 may be any type of wireless electronic device, such as those identified herein.

Example test instrument 11, as described below, is a hardware device. Test instrument 11 may include one or more processing devices 15, examples of which are described herein, to control operation of circuitry 10 and to determine interference in the test channel. Test instrument 11 is configured to send test signals to DUT 14, to receive responses from the DUT in the form of response signals, and to analyze the response signals to determine if the DUT is operating correctly. The test signals may include data packets that instruct operation of the DUT and the response signals may include data packets that contain information about how the DUT operated in response to the test signals. Example test instrument 11 may also be configured to establish connection to DUT 14 prior to sending test signals to the DUT. Any protocol may be used to establish such connection. In a non-limiting example, DUT 14 may be configured to output an advertisement packet over wireless test channel 16 that is within range of test instrument 11 to enable test instrument 11 to identify that DUT 14 is available for wireless connection. Test instrument 11 may respond to the advertisement packet by sending a request packet to DUT 14 to request wireless connection to the DUT 14. DUT 14 may respond to the request packet by sending an acknowledgement packet to test instrument 11. The acknowledgement packet may indicate that DUT 14 has received the request packet successfully and that a wireless connection between the DUT and test instrument 11 is available or has been established. Examples of wireless connections that may be established in this manner include, but are not limited to, short-range wireless connections such as those implemented under the Bluetooth® standard. In some examples, short-range wireless connections may be 40 meters (m) or less, 30 m or less, 20 m or less, 10 m or less, and so forth.

In some implementations, circuitry 10 includes vector signal generator (VSG) 17, vector signal analyzer (VSA) 19, antenna 20, splitter 21, switches 22 and 24, and internal loopback (ILO) circuit 25.

Antenna 20 is an electrical conductor that is configured to send signals such as data packets over wireless test channel 16 to DUT 14. Antenna 20 is also configured to receive signals such as data packets from DUT 14 and other devices over wireless test channel 16. In this example, wireless test channel 16 includes one or more frequencies over which signals can be transmitted wirelessly between test system 12 and DUT 14. Some implementations may include a wired or partially wired test channel in place of wireless test channel 16, as described herein. In wired implementations, antenna 20 may be omitted from the hardware.

An example VSG 17 is a hardware device configured to generate signals including data packets and to output those signals to DUT 14 over wireless test channel 16. The signals may be or include radio frequency (RF) signals for testing a DUT and/or for establishing connection to a DUT. For example, VSG 17 may be configured to generate request packets and to output the request packets over wireless test channel 16 to establish connection with the DUT and/or to generate data packets containing test vectors used to test the DUT and to output those data packets containing test vectors to the DUT over wireless test channel 16.

An example VSA 19 is a hardware device configured to receive signals containing data packets from wireless test channel 16 and to identify the signals by measuring parameters, such as a magnitude and/or a phase, of the received signals. For example, VSA 19 may be configured to compare a received signal to one or more reference signals or to one or more thresholds to identify one or more parameters for the received signal. VSA 19 may be configured to provide analog or digital versions of the received signals to processing device(s) 15 in test instrument 11 for processing.

In some implementations, VSG 17 and VSA 19 may be separate hardware devices. In some implementations, VSG 17 and VSA 19 may be combined into a single hardware device. In some implementations, VSG 17 and VSA 19 may be implemented using one or more semiconductor devices such as transistors, diodes, and/or integrated circuits. In some implementations, VSG 17 and VSA 19 may be implemented using one or more processing devices, such as those described herein, that are configured to execute instructions stored in memory to implement VSA and VSG functions. In some implementations, VSG 17 and VSA 19 may be implemented using a combination of one or more semiconductor devices and one or more processing devices.

In some implementations, splitter 21 is a hardware device, which is electrically connectable to VSG 17 and to VSA 19 via switches 22 and 24, respectively, and which is electrically connected to antenna 20. Splitter 21 includes active and/or passive circuitry to receive, to copy, to route, and to output signals. In some implementations, splitter 21 is configured to receive signals from VSG 17 at port 21a and to output copies of the received signals at ports 21b and 21c. The copies of the signals output by splitter 21 at ports 21b and 21c may have lower (reduced) power(s) than the original signal at input port 21a. For example, each signal output at ports 21b and 21c may have about half of the signal power as a corresponding signal received at port 21a. Splitter 21 is also configured to receive signals such as, but not limited to, interference signals on the test channel, from antenna 20 at port 21c and to output those same signals at port 21b to VSA 19. If there is interference while VSG 17 is transmitting, the output of splitter 21 to VSA 19 becomes the signal from the VSG plus interference signal(s).

Switches 22 and 24 may be electronic switches, mechanical switches, or electromechanical switches. In some implementations, switches 22 and 24 are controllable to toggle along arcs 22a and 24a, respectively, between a first configuration and a second configuration, which are described below.

Processing device(s) 15 on test instrument 11 may control operation of switches 22 and 24 and operation of VSG 17 and VSA 19 in accordance a test program executing on the processing device(s). Processing device(s) 15 may include any type of device that is programmable to perform a function. Examples of different types of processing devices that may be used are described herein.

In some implementations, a control system of the type described below may include processing device(s) 26. The control system, alone or in combination with test instrument 11, may control operation of switches 22 and 24 and operation of VSG 17 and VSA 19 in accordance a test program executing on processing device(s) 26.

ILO circuit 25 may be or include an electrically conductive conduit that is connectable at different ends 25a and 25b thereof to switches 22 and 24, respectively. Making a connection between both ends 25a and 25b of ILO circuit 25 and respective switches 22 and 24 creates an electrical circuit between VSA 17 and VSG 19, through which electrical signals may pass directly between VSA 17 and VSG 19 within test instrument 11.

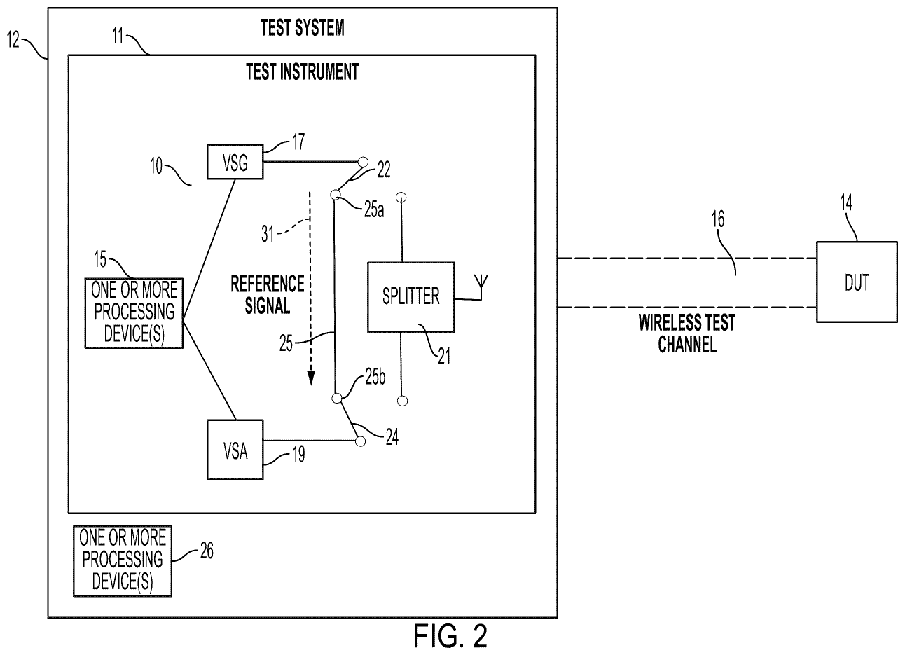

As shown in FIG. 2, in the first configuration, switches 22 and 24 are configured to electrically connect to ILO circuit 25 and thereby electrically connect VSG 17 to VSA 19 via ILO circuit 25. In the first configuration, signals pass directly between VSG 17 and VSA 19—for example, from VSG 17, through ILO circuit 25, to VSA 19. In this example configuration, the signals from VSG 17 do not pass through splitter 21 to antenna 20.

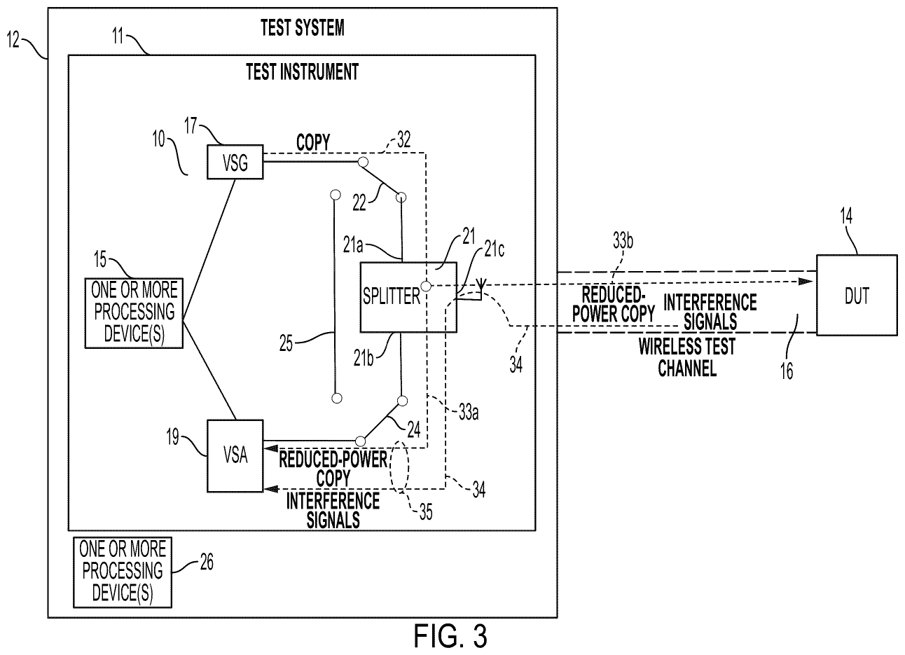

As shown in FIG. 3, in the second configuration, switch 22 is configured to electrically connect VSG 17 to splitter 17 and thereby electrically connect VSG to antenna 20 via splitter 21. Switch 24 is configured to electrically connect VSA 19 to splitter 21 and thereby electrically connect VSA 19 to antenna 20 via splitter 21. In the second configuration, signals pass among splitter 21, VSG 17, antenna 20, and VSA 19. In an example operation in the second configuration, VSG 17 outputs signals, and splitter 21 generates reduced-power copies of the signals from VSG 17 and sends these reduced-power copies to VSA 19 and to antenna 20. Meanwhile, splitter 21 receives signals from antenna 20 and outputs those received signals from antenna 20 to VSA 19.

Splitter 21 is configured to output, to VSA 19, the signals received from antenna 20 and reduced-power copies of the signal received from VSG 17 at the same time via port 21b (which is electrically connected to VSA 19 in the second configuration), such that the signals received from antenna 20 and the reduced-power copies of signals received from VSG 17 overlap at port 21b. In the examples described herein, the “same time” includes at least part of the reduced-power copies of signals from VSG 17 and at least part of the signals from antenna 20 being output from port 21b to VSA 19 at the same time. The effect of the signal overlap may be to incorporate interference, if any, from test channel 16 into the signals output by VSG 17 including reduced-power copies thereof, thereby allowing VSA 19 to perceive the combined VSG signals and interference as they would appear on wireless test channel 16. The combined VSG signals and interference is thus referred to as the test channel signal, since the combined VSG signals and interference are similar to, or equivalent to, the combination of VSG signals and interference that appear on wireless test channel 16. For example, the interference fading (path loss) to the test instrument and to the DUT may be unknown. So, the ratio of the combined signals may not be identical to what is on test channel 16.

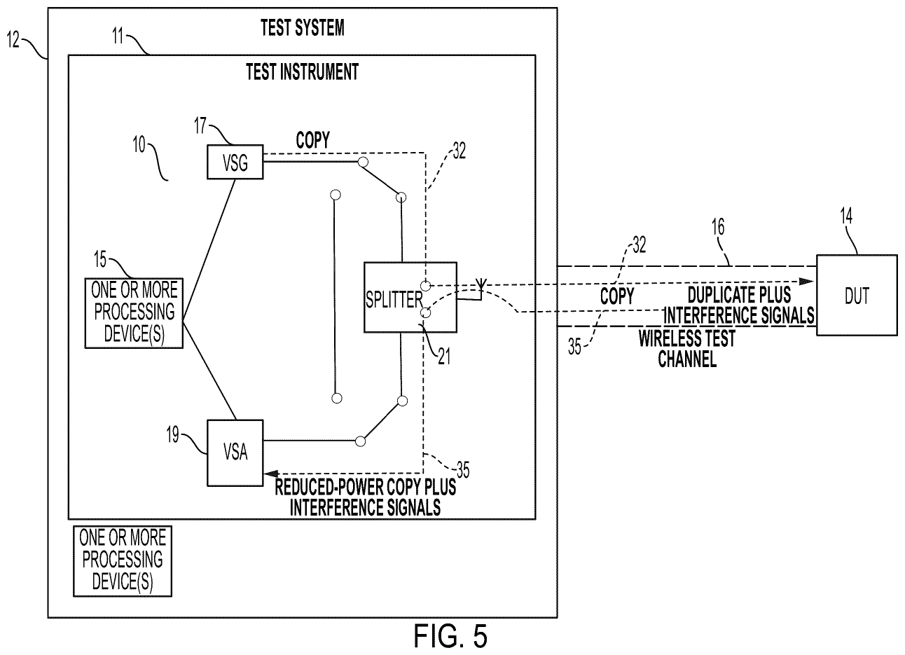

In the foregoing example, the interference, which is part of the test channel signal, includes signals received from wireless test channel 16. VSG signals are received at VSA 19 from VSG 17 via the splitter. In some implementations, splitter 21 is configured so that all VSG signals are output from antenna 20 to wireless test channel 16 and then received by antenna 20 on the wireless test channel 16 at a same time as the interference is received by antenna 20. In this example, the entirety of the test channel signal is detected by antenna 20 and is passed from antenna 20 to splitter 21 and from splitter 21 to VSA 19. This example is described with respect to FIG. 5 below.

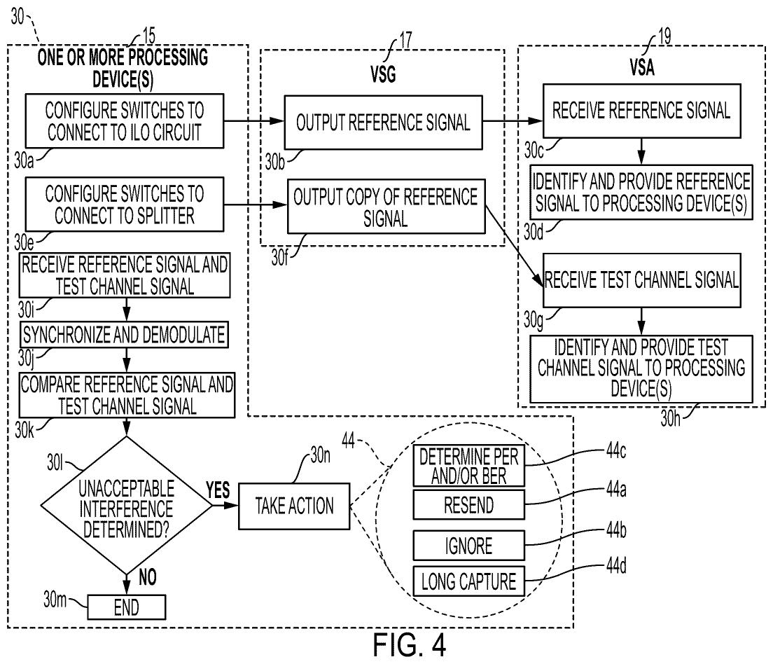

FIG. 4 is a flowchart showing operations included in an example process 30, which may be performed by the components of FIGS. 1 to 3, for determining whether there is an unacceptable amount of interference in a test channel and for taking action based on whether there is an unacceptable amount of interference in the test channel. The example operations of process 30 under “one or more processing devices(s)” may be performed in whole or part by processing devices(s) 15; the example operations of process 30 under “VSG” may be performed in whole or part by VSG 17; and the example operations of process 30 under “VSA” may be performed in whole or part by VSA 19.

Process 30 includes processing device(s) 15 configuring (30a) switches 22 and 24 to electrically connect to ILO circuit 25 in the configuration shown in FIG. 2, namely the first configuration, so that signals output from VSG 17 can pass directly from VSG 17 to VSA 19; in other words, so that those signals do not pass through splitter 21 and antenna 20. Referring also to FIG. 2, processing device(s) 15 control VSG 17 to output (30b) a reference signal 31. In some implementations, reference signal 31 may be a signal that test instrument 11 would send to DUT 14 or that test instrument 11 is sending to DUT 14 as part of a testing process. For example, reference signal 31 may be any type of signal, such as the test signals or the request packets described above. In some implementations, reference signal 31 may be a random signal that would not be sent to the DUT. For example, reference signal 31 may be a random signal generated by the VSG that is simply used to test for interference on wireless test channel 16.

VSA 19 receives (30c) reference signal 31 via ILO circuit 25. VSA 19 is configured to identify (30d) reference signal 31. VSA 19 may identify reference signal 31 by measuring parameters, such as a magnitude and/or a phase, of reference signal 31. VSA 19 outputs (30d) the reference signal 31 to processing device(s) 15. The output reference signal may be an analog or digital version of original reference signal 31, which itself may be an analog or digital signal.

In some implementations, the reference signal may be obtained using techniques other than the internal loopback of ILO circuit 25. For example, switches 22 and 24 may be configured, and VSG 17 may be controlled, to output a reference signal to wireless test channel 16 or directly to another device. The reference signal may be obtained form wireless test channel 16 in the absence of interference.

Process 30 includes processing device(s) 15 configuring (30e) switches 22 and 24 to electrically connect to splitter 21 in the configuration shown in FIG. 3, namely the second configuration, so that signals output from VSG 17 pass through splitter 21. Processing device(s) 15 control VSG 17 to output (30f) a signal that is a copy 32 of reference signal 31. Outputting the copy 32 of reference signal 31 may be referred to herein as resending or retransmitting reference signal 31 or as outputting another instance of reference signal 31. In this example, splitter 21 receives the copy 32 of reference signal 31 on port 21a and outputs, on port 21b, a reduced-power copy 33a of reference signal 31. As noted above, each signal output at ports 21b and 21c may have about half of the signal power as a corresponding signal received at port 21a. Port 21b is electrically connected to VSA 19 in the second configuration.

Splitter 21 may also output a reduced-power copy 33b of reference signal 31 on port 21c, which is electrically connected to antenna 20. Reduced-power copies 33a and 33b may each have about half the signal power as reference signal 31. Antenna 20 sends reduced-power copy 33b of reference signal 31 to wireless test channel 16 in this example. Splitter 21 is also configured to receive, on port 21c, interference signals 34 from antenna 20, which are obtained from wireless test channel 16, and to output interference signals 34 on port 21b. In some implementations, interference signals 34 may include any signals on wireless test channel 16 that are not part of communications between test system 12 and DUT 14 that can be detected by antenna 20. Interference signals 34, if any, may also include signals attributed to the reduced-power copy 33b of reference signal 31 that was output from splitter 21 to wireless test channel 16.

In this example, VSA 19 receives (30g), from port 21b of splitter 21, a test channel signal 35 that includes (i) reduced-power copy 33a of reference signal 31 from splitter 21 and (ii) interference signals 34, if any, from antenna 20.

Copy 32 of reference signal 31 and interference signals 34 may arrive at splitter 21 at or about the same time from, respectively, VSG 17 and antenna 20 and, therefore, reduced-power copy 33a of reference signal 31 and interference signals 34 may overlap to produce test channel signal 35 at splitter 21. Accordingly, test channel signal 35 received at VSA 19 is similar, although not necessarily identical, to the combination of the reference signal and any interference as the two signals would appear on wireless test channel 16. The issue of interference fading (path loss) may affect the combination, as noted. VSA 19 is configured to identify (30h) test channel signal 35. As described above, VSA 19 may identify test channel signal 35 by measuring parameters, such as a magnitude and/or a phase, of test channel signal 35. VSA 19 outputs (30h) test channel signal 35 to processing device(s) 15. The output test channel signal may be an analog or digital version of original test channel signal 35, which itself may be an analog or digital signal.

As explained above, in some implementations, splitter 21 may be configured so that a full-power copy 32 of reference signal 31 received on port 21a of splitter 21 is output from antenna 20 to wireless test channel 16 and then detected by antenna 20 on wireless test channel 16, along with interference signals 34. In this configuration, the signal paths among VSG 17, splitter 21, antenna 20, and VSA 19 are as shown in FIG. 5. As shown in FIG. 5, in this example, the entirety of test channel signal 35 is detected by antenna 20, and is then passed from splitter 21 to VSA 19. VSA 19 identifies and outputs (30h) the test channel signal in analog or digital form, as described above.

Processing device(s) 15 receive (30i) reference signal 31 and test channel signal 35 from VSA 17 as described above. Processing device(s) 15 synchronize (30j) reference signal 31 and test channel signal 35. In some implementations, synchronizing is performed with respect to the time, amplitude, phase, and frequency offset of reference signal 31 and test channel signal 35. In some implementations, synchronizing may include identifying parts of each signal, such as their preambles, so that, when reference signal 31 and test channel signal 35 are compared in operation 30k of process 30 described below, the two signals are compared relative to the same point in time of each signal. Processing device(s) 15 may also demodulate (30j) reference signal 31 and test channel signal 35. Demodulation may include obtaining original information signals from a modulated carrier signal, such as a frequency-modulated carrier signal. In some implementations, reference signal 31 and test channel signal 35 may not be modulated and, therefore, demodulation need not be performed.

Processing device(s) 15 compare (30k) a version of reference signal 31 to a version of test channel signal 35 to determine if there is a difference between the reference signal and the test channel signal. In some implementations, the version of reference signal 31 is a demodulated version of the reference signal 31, and the version of test channel signal 35 is a demodulated the version of test channel signal 35. In some implementations, the version of reference signal 31 is the reference signal itself unaltered, and the version of test channel signal 35 is the test channel signal itself unaltered. As noted above, the comparison (30k) may be performed relative to a same point in time of each signal.

The difference, if any, between the reference signal and the test channel signal following synchronization (e.g., synchronization of time, amplitude, phase, frequency, and/or other characteristics) is indicative of the presence and the amount interference in the test channel signal. More specifically, because test channel signal 35 is based on reference signal 31 plus interference signals 34 (if any) from wireless test channel 16, a difference between test channel signal 35 and reference signal 31 (or versions thereof) can be attributed to interference on wireless test channel 16.

In some implementations, the comparing (30k) may be performed by processing device(s) 15 performing a cross-correlation between the version of reference signal 31 and the version of test channel signal 35. Cross-correlation is a measurement of the difference between the version of reference signal 31 and the version of test channel signal 35. In an example, cross-correlation is a measure of a difference between the version of reference signal 31 and the version of test channel signal 35 as a function of a displacement of one signal relative to the other signal. If the two signals are the same, then the cross-correlation should produce a value of one. If the signals are different, then the cross-correlation should produce a value other than one, with the magnitude of the value being based on the amount of the difference. For example, if two signals have a cross-correlation value of zero, this means that the two signals have no identical components.

In some implementations, the comparison (30k) may be performed by processing device(s) 15 subtracting one signal from the other. For example, because the version of reference signal 31 and the version of test channel signal 35 are synchronized in time, processing device(s) 15 may subtract the version of reference signal 31 from the version of test channel signal 35 or the version of test channel signal 35 from the version of reference signal 31. The resulting difference is based on, or equal to, a measure of the amount of interference on wireless test channel 16.

Processing device(s) 15 compare the determined difference between the version of reference signal 31 and the version of test channel signal 35 to a predefined threshold to determine (301) whether there is greater than a predefined amount—for example, an unacceptable amount—of interference in wireless test channel 16. This predefined threshold may be programmed into processing device(s) 15 by a user prior to testing or it may be programmed into processing device(s) 15 by a test program. The predefined threshold may be is based, at least in part, on the RF and baseband stability of test system 12. The predefined threshold may be based on distribution data for cross-correlation results when there is no interference in the test channel.

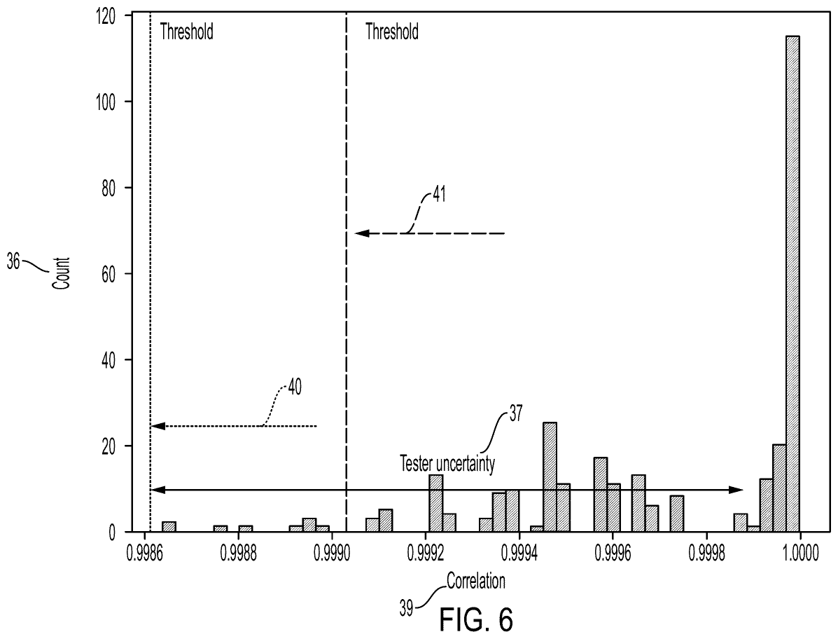

By way of example, FIG. 6 is a graph showing cross-correlation values 39 of signals captured from wireless test channel 16 when there is known to be no interference on wireless test channel 16. The counts 36 are representations of random variations generated by test system 12 during its operation, which may be referred to as “tester uncertainty” 37. The predefined threshold may be selected to reduce the chances that this noise will affect determining the presence of interference on the test channel. For example, by selecting threshold 40 to be the predefined threshold, the likelihood of noise (corresponding to counts 36) in the test system being identified as interference on wireless test channel may be reduced. For example, by selecting threshold 41 to be the predefined threshold, the likelihood of noise (corresponding to counts 36) in the test system preventing process 30 from indicating that there is no interference or less than the acceptable amount of interference on the wireless test channel may be reduced. Threshold 41 may be used as the predefined threshold in this example. In this regard, in some implementations, it may be more important to ensure that interference on wireless test channel 16 is identified rather that to prevent noise in the test system from being identified as interference on the wireless test channel. Since test system 12 is independent of whether interference present, a false positive (e.g., there is no interference but process 30 indicates interference) would only increase the number of data packets sent, but has no impact on the true PER.

Referring back to FIG. 4, in some implementations, if the difference is less than the predefined threshold, then wireless test channel 16 is deemed not have an unacceptable amount of interference. For example, if the difference is less than the predefined threshold, then wireless test channel 16 may be deemed to have no interference. In this case, testing may end (30m), begin again, or continue. In some implementations, if the difference is greater than or equal to the predefined threshold, then wireless test channel 16 is deemed to have an unacceptable amount of interference. For example, if the difference is greater than the predefined threshold, then wireless test channel 16 may be deemed to have non-zero interference. In this case, processing device(s) may output a trigger indicating that one or more actions 44 are to be taken (30n).

In some implementations, processing device(s) 15 may configure switches 22 and 24 so that VSG 17 electrically connects to antenna 20 in the second configuration (FIG. 3) and may control VSG 17 to resend (44a) copy 32 of reference signal 31 so that reduced-power copy 33b of reference signal 31 is again transmitted by antenna 20 onto wireless test channel 16. This may be done, for example, if interference testing is performed concurrently with communications to the DUT. For example, if process 30 determines that there is an unacceptable amount of interference (301) on wireless test channel 16, processing device(s) 15 may make an inference about whether the reduced-power copy 33b of the reference signal, and one or more data packets contained therein, reached DUT 14 via test channel 16 and/or could be understood by DUT 14. That is, processing device(s) 15 may infer that one or more of the data packets did not reach DUT 14 and/or could not be understood by DUT 14. In that case, resending the reduced-power copy 33b of the reference signal to wireless test channel 16 may increase the likelihood that DUT 14 will receive the version 33 of reference signal 31 (e.g. by trying again). The reduced-power copy 33b of the reference signal may be resent any number of times while there is an unacceptable amount of interference on the test channel. In some implementations, DUT 14 may acknowledge the reduced-power copy 33b of the reference signal, in which case resending (44a) may cease.

In some implementations, processing device(s) may ignore (44b) data packets received when unacceptable amounts of interference are determined to be on the test channel. The rationale here is that these data packets may be corrupt and that (i) corrupted data packets may adversely affect testing and/or (ii) processing resources may be wasted by attempting to interpret and to process corrupted data packets. Processing device(s) 15 may wait until the amount of interference on the test channel is at acceptable levels before its stops ignoring (44b) data packets.

In some implementations, processing device(s) 15 may determine (44c) the PER and/or BER resulting from the interference determined on the test channel. This may be done, in part, by tracking of a first number of packets in the test channel signal that contains interference and subtracting the first number of packets from a second number of packets received from DUT 14 that had no interference. In some implementations, a PER determination is only triggered when the DUT does not reply to a transmitted signal, such as a request packet, with an acknowledgment. In some implementations, a PER or BER determination may be performed at any time.

In some implementations, processing device(s) 15 may control VSA 19 to perform a long capture (44d) of data packets on wireless test channel 16 when unacceptable amounts of interference are determined on the test channel. A long capture may include capturing a predefined number of data packets from the wireless test channel before and/or after a point in time. For example, the predefined number of data packet may be 10, 15, 20, and so forth. Implementing a long capture may reduce the proportion of corrupted data packets that are received by the test system at a given time and may enable recovery of corrupted data packets.

In some implementations, processing device(s) 15 may perform two or more of operations 44a to 44d concurrently. For example, operation 44c may be performed concurrently with operations 44a and/or 44d.

In some implementations, process 30 may be configured to detect interference resulting from collisions of data packets on wireless test channel 16. For example, signals for short range wireless protocols, such as the Bluetooth® standard, may include advertising packets (ADV) sent from DUT 14, request packets such as SCAN-REQ packets sent by test system 12 in response to the advertising packets, and acknowledgement packets such as SCAN_RESP packets sent by the DUT to the test system if the DUT correctly decodes the request packets. Request packets such as SCAN_REQ request a connection to the DUT. Acknowledgement packets such as SCAN_RESP packets act as an acknowledgement that the DUT received the request packets, such as SCAN-REQ, packets correctly.

In the Bluetooth® standard communications, interference may result from collisions of data packets. For example, in a multi-DUT or open-environment test configuration, SCAN_REQ packets sent by test system may collide with other data packets on wireless test channel 16 (e.g., with ADV or SCAN_RESP packets from other DUTs), which produces stray, unintended, and/or unexpected interference signals on the wireless test channel. The DUT, such as DUT 14, may not decode the SCAN_REQ packet correctly because of this interference caused by the collision. Process 30 may be used to infer that one or more SCAN_REQ packets that have collided with other packets in wireless test channel 16 based on their transmission time(s) and times at which interference is detected. To determine a PER, processing device(s) 15 may disregard SCAN_REQ packets that are believed to have collided with other packets on the wireless test channel. Thus, the accuracy of receiver-side PER determinations may be improved. In some implementations, process 30 may be executed when the DUT does not reply to a SCAN_REQ packet, which means that this SCAN_REQ likely collided with another packet.

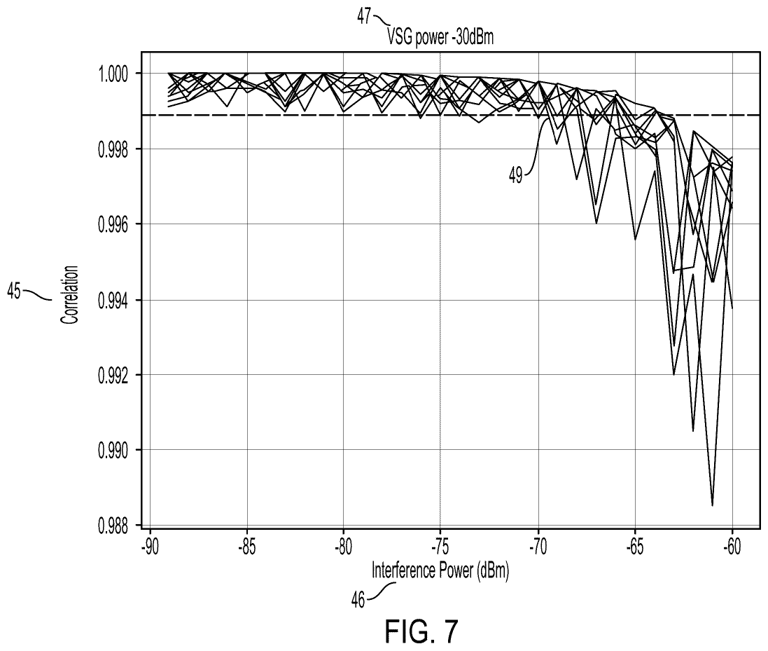

FIG. 7 is a graph showing correlation values 45 for different interference signal powers 46 measured in dBm (decibel-milliwatts). As shown, when VSG 17 transmits SCAN_REQ packets at −30 dBm power 47, the correlation threshold is about 0.999, and process 30 may flag interference when the interference power is higher than around −70 dBm 48, which is where the decrease in correlation begins. The interference may be a result of collision of the transmitted SCAN_REQ packets on the wireless test channel.

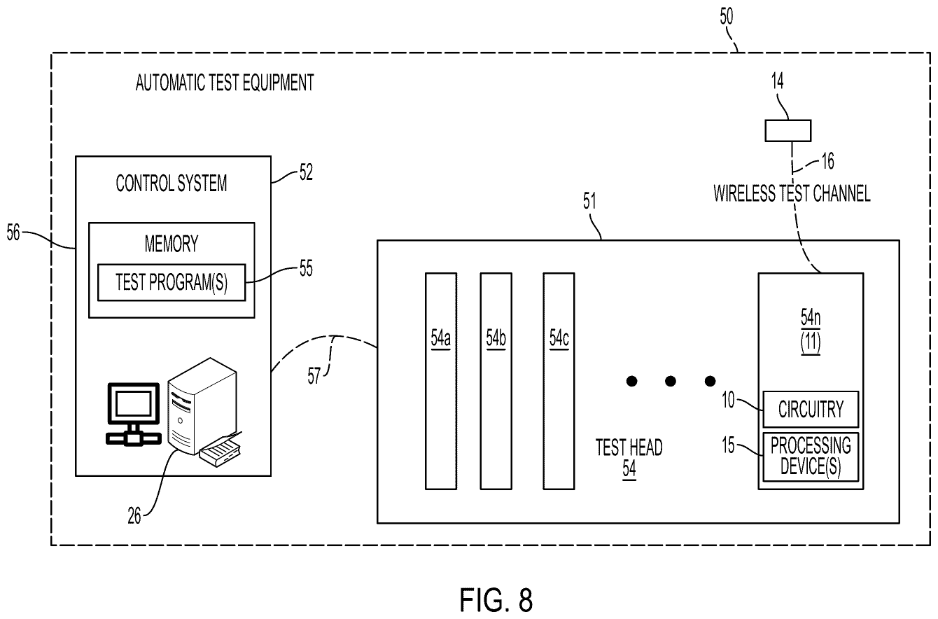

The circuitry 10 of FIGS. 1 to 3 and 5 may be part of ATE. FIG. 8 is a block diagram showing example components of example ATE 50 that includes a testing device/apparatus (referred to also as a “tester”) 51 and a control system 52.

ATE 50 includes a test head 54. Test head 54 includes multiple test instruments 54a to 54n (where n>3), each of which may be configured, as appropriate, to implement testing and/or the functionality of test instrument 11 of FIGS. 1 to 3 and 5. Although only four test instruments are shown, ATE 50 may include any appropriate number of test instruments, including one or more residing outside of test head 54. The test instruments may be hardware devices that may each include one or more processing devices 15 and/or circuitry 10 of FIGS. 1 to 3 and 5 (shown only for test instrument 54n). The test instruments may be configured—for example, programmed—to output test signals to test DUTs, such as DUT 14. The test signals to test the DUTs may be or include commands, instructions, data, parameters, variables, test vectors, and/or any other information designed to elicit response(s) from the DUT. Each test instrument may be configured to establish a wireless connection with a DUT, as described with respect to test instrument 11. Signals for establishing a wireless connection, such as RF signals, may include data packets such as request packets, including those used in short range wireless protocols such as the Bluetooth® standard. The signals may include test signals, such as those described previously. One or more processing devices 15 may also execute instructions to communicate with control system 52 and/or and to analyze responses to the test signals.

One or more wireless test channels, such as test channel 16, are configured between the test head and various DUTs to enable communication between the DUTs and the test instruments. Signals such as RF signals may be transmitted between the test system and a DUT over the wireless test channels. One or more of the test channels may be a wired test channel (not shown), over which signals such as RF signals may be transmitted between the test system and a DUT. For example, a wired test channel may include a transmission line or coaxial cable to transmit RF signals. In some implementations, the test channels may include a combination of wired and wireless test channels. In some implementations, individual test channels may have one or more wired portions and one or more wireless portions.

Control system 52 may be configured—e.g., programmed—to communicate with test instruments 54a to 54n to direct and/or to control testing of the DUTs and to configure circuitry 10 when process 30 is implemented. In some implementations, this communication 57 may be over a computer network or via a direct connection such as a computer bus or an optical medium. In some implementations, the computer network may be or include a local area network (LAN) or a wide area network (WAN). The control system may be or include a computing system comprised of one or more processing devices 26 (e.g., microprocessor(s)) and memory 56 for storing instructions to control operation of the ATE and/or testing. Memory 55 also stores one or more test programs 55 to execute and/or to send to the test instruments for execution. In this regard, control system 52 may be configured to provide test programs 55 and/or test signals to test instruments 54a to 54n in the test head, which the test instrument(s) use to test the DUT. Control system 52 may also be configured to receive DUT response signals (e.g., measurement data) from the test instrument(s) and to determine whether the corresponding DUT has passed or failed testing.

In some implementations, the control functionality is centralized in processing device(s) 26. In some implementations, all or part of the functionality attributed to control system 52 may also or instead be implemented on a test instrument and/or all or part of the functionality attributed to one or more test instruments may also or instead be implemented on control system 52. For example, the control system may be distributed across processing device(s) 15 and one or more of test instruments 54a to 54n.

All or part of the systems and processes described herein including but not limited to process 30 and its modifications may be implemented, configured and/or controlled at least in part by one or more computers using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected.

Actions associated with implementing, configuring, or controlling the test system and processes described herein can be performed by one or more programmable processors executing one or more computer programs to control or to perform all or some of the operations described herein. All or part of the test systems and processes can be implemented, configured, or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

The processes described herein are not limited to use with any particular wireless transmission protocol, such as Bluetooth®. For example, Bluetooth® and Wi-Fi may operate at the same frequency and signals from both protocols can interfere. Performing process 30 in this case will enable identifying that interference is present, including cases where missing data packets are identified, and enable identifying the cases where no co-channel interference exists. Performing process 30 can be used to flag algorithmic problems allowing interference to exist. For example, some algorithms may try to ensure that no interference exists. Process 30 may be useful during development of such algorithms. Process 30 can also be used to evaluate robustness of a receiver when interference occurs. Process 30 can be used to be to capture behavior, such as timing information and the like, of all packets when interference exists. This information may be used to perform an analysis to identify events on the test channel that caused the interference. In this regard, test systems may be designed to avoid interference, so there may be a bug in the system if interference occurs.

All examples described herein are non-limiting.

In the description and claims provided herein, the adjectives “first”, “second”, “third”, and the like do not designate priority or order unless context suggests otherwise. Instead, these adjectives may be used solely to differentiate the nouns that they modify.

Any mechanical or electrical connection herein may include a direct physical connection or an indirect physical connection that includes one or more intervening components. A connection between two electrically conductive components includes an electrical connection unless context suggests otherwise. The signals described herein are electrical signals unless context suggests otherwise.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. A test system comprising:
a signal receiver configured to receive (i) a reference signal and (ii) a test channel signal; and
one or more processing devices configured to compare a version of the reference signal to a version of the test channel signal to determine whether there is a predefined amount of interference in the test channel signal.

2. The test system of claim 1, further comprising:
a signal generator configured to output the reference signal;
wherein the signal receiver is configured to receive the reference signal from the signal generator and to receive at least part of the test channel signal from the test channel, the test channel signal comprising at least part of a copy of the reference signal; and
wherein the one or more processing devices are configured to compare the version of the reference signal to the version of the test channel signal to determine if there is a difference between the version of the reference signal and the version of the test channel signal.

3. The test system of claim 2, wherein if the difference is less than a predefined threshold, then the test channel signal does not have the predefined amount of interference.

4. The test system of claim 3, wherein the predefined threshold is based, at least in part, on radio frequency (RF) and baseband stability of the test system.

5. The test system of claim 2, wherein if the difference is greater than a predefined threshold, then the test channel signal does have the predefined amount of interference; and
wherein the one or more processing devices are configured to cause the signal generator to output a copy of reference signal again if the difference is greater than the predefined threshold.

6. The test system of claim 3, wherein the predefined threshold is based, at least in part, on radio frequency (RF) and baseband stability of the test system.

7. The test system of claim 2, wherein the signal generator comprises a vector signal generator (VSG);
wherein the signal receiver comprises a vector signal analyzer (VSA) and an antenna; and
wherein the test system further comprises switches configured to connect the VSG to the VSA in a first configuration, to connect the VSG to the antenna in a second configuration, and to connect the VSA to the antenna in the second configuration.

8. The test system of claim 1, wherein determining whether there is the predefined amount of interference in the test channel signal comprises performing a correlation between the version of the reference signal and the version of the test channel signal.

9. The test system of claim 1, wherein the one or more processing devices are configured to synchronize the version of the reference signal and the version of the test channel signal prior to determining whether there is the predefined amount of interference in the test channel signal.

10. The test system of claim 1, wherein the reference signal and the test channel signal comprise radio frequency (RF) signals; and
wherein the test channel comprises a wireless test channel.

11. The test system of claim 1, wherein the reference signal and the test channel signal comprise radio frequency (RF) signals; and
wherein the test channel comprises a wired test channel.

12. The test system of claim 1, wherein the test channel signal comprises at least one of interference from one or more other signals in the test channel or a signal directed to the test system by a device under test.

13. The test system of claim 1, wherein the test channel signal comprises a data packet that will cause an acknowledgement if received by a device.

14. The test system of claim 1, wherein when the one or more processing devices determine that there is the predefined amount of interference in the test channel signal, the one or more processing devices are configured to ignore data packets from the test channel.

15. A method comprising:
receiving, at a signal receiver, (i) a reference signal and (ii) a test channel signal; and
comparing a version of the reference signal to a version of the test channel signal to determine whether there is a predefined amount of interference in the test channel signal.

16. The method of claim 15, further comprising:
outputting the reference signal from a signal generator;
wherein the signal receiver receives the reference signal from the signal generator and receives at least part of the test channel signal from the test channel, the test channel signal comprising at least part of a copy of the reference signal; and
wherein comparing the version of the reference signal to the version of the test channel signal comprises comparing the version of the reference signal to the version of the test channel signal to determine if there is a difference between the version of the reference signal and the version of the test channel signal.

17. The method of claim 16, wherein if the difference is less than a predefined threshold, then the test channel signal does not have the predefined amount of interference.

18. The method of claim 17, wherein the predefined threshold is based, at least in part, on radio frequency (RF) and baseband stability of a system that performs the method.

19. The method of claim 16, wherein if the difference is greater than a predefined threshold, then the test channel signal does have the predefined amount of interference; and
wherein the method comprises causing the signal generator to output a copy of reference signal again if the difference is greater than a predefined threshold.

20. The method of claim 17, wherein the predefined threshold is based, at least in part, on radio frequency (RF) and baseband stability of a system that performs the method.

21. The method of claim 16, wherein the signal generator comprises a vector signal generator (VSG);
wherein the signal receiver comprises a vector signal analyzer (VSA) and an antenna; and
wherein the method further comprises configuring switches to connect the VSG to the VSA in a first configuration, to connect the VSG to the antenna in a second configuration, or to connect the VSA to the antenna in a second configuration.

22. The method of claim 15, wherein determining whether there is the predefined amount of interference in the test channel signal comprises performing a correlation between the version of the reference signal and the version of the test channel signal.

23. The method of claim 15, further comprising:
synchronizing the version of the reference signal and the version of the test channel signal prior to determining whether there is interference in the test channel signal.

24. The method of claim 15, wherein the reference signal and the test channel signal comprise radio frequency (RF) signals; and
wherein the test channel comprises a wireless test channel.

25. The method of claim 15, wherein the reference signal and the test channel signal comprise radio frequency (RF) signals; and
wherein the test channel comprises a wired test channel.

26. The method of claim 15, wherein the test channel signal comprises at least one of interference from one or more other signals in the test channel or a signal directed to a system that performs the method by the DUT.

27. The method of claim 15, wherein the test channel signal comprises a data packet that will cause an acknowledgement if received by a device.

28. The method of claim 15, wherein when there is the predefined amount of interference in the test channel signal, the method further comprises ignoring data packets from the test channel.

29. A test system comprising:
a signal generator to output a data packet to a test channel;
a signal receiver configured to receive (i) a reference signal and (ii) a test channel signal; and
one or more processing devices configured to compare a version of the reference signal to a version of the test channel signal to make an inference about whether a data packet reached a device under test (DUT) via the test channel, and to determine a performance metric based on the inference.

30. The test system of claim 29, wherein the one or more processing devices configured to ignore data packets on the test channel if the inference is that the data packet did not reach the DUT.

31. The test system of claim 30, wherein the one or more processing devices are configured to determine that there is a predefined amount of interference on the test channel if a difference between the version of the reference signal and the version of the test channel signal exceeds a threshold, the inference being that the data packet did not reach the DUT if the predefined amount of interference is determined.

32. The test system of claim 31, wherein the one or more processing devices are configured to cause the signal receiver to implement a long capture comprised of a predefined number of data packets when interference is detected.

33. The test system of claim 31, wherein the one or more processing devices are configured to determine that there is a predefined amount of interference on the test channel if a difference between the version of the reference signal and the version of the test channel signal exceeds a threshold; and
wherein the wherein the one or more processing devices are configured to output a trigger in response to determining that there is the predefined amount of interference on the test channel, the trigger for instructing that further action be taken.

34. The test system of claim 31, wherein the one or more processing devices are configured to ignore data packets that are received when there is the predefined amount of interference on the test channel.

35. The test system of claim 29, wherein the performance metric comprises a packet error rate.
